(19) United States
(12) Patent Application Publication
(10) Pub. No.: US 2010/0006873 A1
(43) Pub. Date: Jan. 14, 2010

(54) HIGHLY POLARIZED WHITE LIGHT SOURCE BY COMBINING BLUE LED ON SEMIPOLAR OR NONPOLAR GaN WITH YELLOW LED ON SEMIPOLAR OR NONPOLAR GaN

(75) Inventors: James W. Raring, Goleta, CA (US); Daniel F. Feezell, Goleta, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: SORAA, INC., Goleta, CA (US)

(21) Appl. No.: 12/481,543

(22) Filed: Jun. 9, 2009

Related U.S. Application Data
(60) Provisional application No. 61/075,339, filed on Jun. 25, 2008.
(60) Provisional application No. 61/076,596, filed on Jun. 27, 2008.

(51) Int. Cl. H01L 33/00

(52) U.S. Cl. 257/90; 438/28; 257/76; 257/E33.056; 257/E33.013

(57) ABSTRACT

A packaged light emitting device. The device has a substrate member comprising a surface region. The device also has two or more light emitting diode devices overlying the surface region. Each of the light emitting diode device is fabricated on a semipolar or nonpolar GaN containing substrate. The two or more light emitting diode devices are fabricated on the semipolar or nonpolar GaN containing substrate emits substantially polarized emission.

### CROSS-REFERENCE TO RELATED APPLICATIONS

This application claims priority to U.S. Provisional Patent Application No. 61/075,339 filed Jun. 25, 2008, entitled “COPACKAGING CONFIGURATIONS FOR NONPOLAR GaN AND/OR SEMIPOLAR GaN LEDs” by inventors James W. Raring, and Daniel Feezell, and to U.S. Provisional Patent Application No. 61/076,596 filed Jun. 27, 2008, entitled “COPACKAGING CONFIGURATIONS FOR NONPOLAR GaN AND/OR SEMIPOLAR GaN LEDs” by inventors James W. Raring, Daniel Feezell and Mark P. D'Evelyn both of which are commonly assigned and incorporated by reference herein for all purposes.

### DESCRIPTION OF EMBODIMENTS OF THE INVENTION

The present invention relates generally to lighting techniques. More specifically, embodiments of the invention include techniques for combining different colored LED devices, such as blue and yellow, fabricated on bulk semipolar or nonpolar materials. Merely by way of example, the invention can be applied to applications such as white lighting, multi-colored lighting, lighting for flat panels, other optoelectronic devices, and the like.

In the late 1800's, Thomas Edison invented the light bulb. The conventional light bulb, commonly called the “Edison bulb,” has been used for over one hundred years. The conventional light bulb uses a tungsten filament enclosed in a glass bulb sealed in a base, which is screwed into a socket. The socket is coupled to an AC power or DC power source. The conventional light bulb can be found commonly in houses, buildings, and outdoor lightings, and other areas requiring light. Unfortunately, drawbacks exist with the conventional Edison light bulb. That is, the conventional light bulb dissipates much thermal energy. More than 90% of the energy used for the conventional light bulb dissipates as thermal energy. Additionally, the conventional light bulb routinely fails often due to thermal expansion and contraction of the filament element.

To overcome some of the drawbacks of the conventional light bulb, fluorescent lighting has been developed. Fluorescent lighting uses an optically clear tube structure filled with a halogen gas and, which typically also contains mercury. A pair of electrodes is coupled between the halogen gas and couples to an alternating power source through a ballast. Once the gas has been excited, it discharges to emit light. Typically, the optically clear tube is coated with phosphors, which are excited by the light. Many building structures use fluorescent lighting and, more recently, fluorescent lighting has been fitted onto a base structure, which couples into a standard socket.

Solid state lighting techniques have also been used. Solid state lighting relies upon semiconductor materials to produce light emitting diodes, commonly called LEDs. At first, red LEDs were demonstrated and introduced into commerce. Red LEDs use Aluminum Indium Gallium Phosphide or AlInGaP semiconductor materials. Most recently, Shuji Nakamura pioneered the use of InGaN materials to produce LEDs emitting light in the blue color range for blue LEDs. The blue colored LEDs led to innovations such as solid state white lighting, the blue laser diode, which in turn enabled the Blu-Ray™ (trademark of the Blu-Ray Disc Association) DVD player, and other developments. Other colored LEDs have also been proposed.

High intensity UV, blue, and green LEDs based on GaN have been proposed and even demonstrated with some success. Efficiencies have typically been highest in the UV-violet, dropping off as the emission wavelength increases to blue or green. Unfortunately, achieving high intensity, high-efficiency GaN-based green LEDs has been particularly problematic. The performance of optoelectronic devices fabricated on conventional c-plane GaN suffer from strong internal polarization fields, which spatially separate the electron and hole wave functions and lead to poor radiative recombination efficiency. Since this phenomenon becomes more pronounced in InGaN layers with increased indium content for increased wavelength emission, extending the performance of UV or blue GaN-based LEDs to the blue-green or green regime has been difficult. Furthermore, since increased indium content films often require reduced growth temperature, the crystal quality of the InGaN films is degraded. The difficulty of achieving a high intensity green LED has lead scientists and engineers to the term “green gap” to describe the unavailability of such green LED. In addition, the light emission efficiency of typical GaN-based LEDs drops off significantly at higher current densities, as are required for general illumination applications, a phenomenon known as “roll-over.” Other limitations with blue LEDs using c-plane GaN exist. These limitations include poor yields, low efficiencies, and reliability issues. Although highly successful, solid state lighting techniques must be improved for full exploitation of their potential. These and other limitations may be described throughout the present specification and more particularly below.

From the above, it is seen that techniques for improving optical devices is highly desired.

### BRIEF SUMMARY OF THE INVENTION

According to the present invention, techniques for lighting are provided. More specifically, embodiments of the invention include techniques for combining different colored LED devices, such as blue and yellow, fabricated on bulk semipolar or nonpolar materials. Merely by way of example, the invention can be applied to applications such as white lighting, multi-colored lighting, lighting for flat panels, other optoelectronic devices, and the like.

We understand that recent breakthroughs in the field of GaN-based optoelectronics have demonstrated the great potential of devices fabricated on bulk nonpolar and semipolar GaN substrates. The lack of strong polarization induced electric fields on these orientations leads to a greatly enhanced radiative recombination efficiency in InGaN emitting layers over conventional devices fabricated on c-plane GaN. Furthermore, the electronic band structure along with the anisotropic nature of the strain leads to highly polarized light emission, which will offer several advantages in applications such as display backlighting.

Of particular importance to the field of lighting is the progression of light emitting diodes (LED) fabricated on semipolar GaN substrates. Such devices making use of InGaN light emitting layers have exhibited record output powers at extended operation wavelengths into the blue region (430-470 nm) and the green region (510-530 nm). One promising semipolar orientation is the (11-22) plane. This plane is inclined by 58.4° with respect to the c-plane. University of California, Santa Barbara has produced highly efficient LEDs on (11-22) GaN with over 65 mW output power at 100 mA for blue-emitting devices [1], over 35 mW output power at 100 mA for blue-green emitting devices [2], and over 15 mW of power at 100 mA for green-emitting devices [3]. In [3] it was shown that the indium incorporation on semipolar (11-22) GaN is comparable to or greater than that of c-plane GaN, which provides further promise for achieving high crystal quality extended wavelength emitting InGaN layers.

This rapid progress of semipolar GaN-based emitters at longer wavelengths indicates the imminence of a yellow LED operating in the 560-590 nm range and/or possibly even a red LED operating in the 625-700 nm range on semipolar GaN substrates. Either of these breakthroughs would facilitate a white light source using only GaN based LEDs. In the first case, a blue semipolar LED can be combined with a yellow semipolar LED to form a fully GaN/InGaN-based LED white light source. In the second case, a blue semipolar LED can be combined with a green semipolar LED and a red semipolar LED to form a fully GaN/InGaN-based LED white light source. Both of these technologies would be revolutionary breakthroughs since the inefficient phosphors used in conventional LED based white light sources can be eliminated. Very importantly, the white light source would be highly polarized relative to LED/phosphor based sources, in which the phosphors emit randomly polarized light. Furthermore, since both the blue and the yellow or the blue, green, and red LEDs will be fabricated from the same material system, great fabrication flexibilities can be afforded by way of monolithic integration of the various color LEDs. It is important to note that other semipolar orientations exist such as (10-1-1) plane. White light sources realized by combining blue and yellow or blue, green, and red semipolar LEDs would offer great advantages in applications where high efficiency or polarization are important. Such applications include conventional lighting of homes and businesses, decorative lighting, and backlighting for displays. There are several embodiments for this invention including copackaging discrete blue-yellow or blue-green-red LEDs, or monolithically integrating them on the same chip in a side-by-side configuration, in a stacked junction configuration, or by putting multi-color quantum wells in the same active region. Further details of the present invention are described throughout the present specification and more particularly below.

In a specific embodiment, the present invention provides a packaged light emitting device. The device has a substrate member comprising a surface region. The device also has two or more light emitting diode devices overlying the surface region. Each of the light emitting diode device is fabricated on a semipolar or nonpolar GaN containing substrate. The two or more light emitting diode devices are fabricated on the semipolar or nonpolar GaN containing substrate emits substantially polarized emission. As used herein, the terms “substantially polarized” shall be interpreted by ordinary meaning and generally refers to plane polarization. Of course, there can be other variations, modifications, and alternatives.

In an alternative specific embodiment, the present invention provides a monolithic light emitting device. The device has a bulk GaN containing semipolar or nonpolar substrate comprising a surface region. The device also has an n-type GaN containing layer overlying the surface region. The n-type GaN containing layer has a first region and a second region. The device also has a first LED device region having a first color characteristic provided on the first region and a second LED device region having a second color characteristic provided on the second region. In a specific embodiment, the first color characteristic is blue and the second color characteristic is yellow.

In yet an alternative embodiment, the present invention provides a monolithic light emitting device. The device has a bulk GaN containing semipolar or nonpolar substrate comprising a surface region. The device has an n-type GaN containing layer overlying the surface region. The n-type GaN containing layer has a first region and a second region. The device has a first LED device region having a first color characteristic provided on the first region, a second LED device region having a second color characteristic provided on the second region, and a third LED device region having a third color characteristic provided on the third region.

In still an alternative embodiment, the present invention provides a light emitting device. The device has a bulk GaN containing semipolar or nonpolar substrate. The bulk GaN containing semipolar or nonpolar substrate comprises a surface region and a bottom region. In a specific embodiment, the device has an n-type GaN containing material overlying the surface region. The device has a blue LED device region overlying the surface region, a green LED device region overlying the blue LED device region, and a red LED device region overlying the green LED device region to form a stacked structure.

Still further, the present invention provides a light emitting device. The device has a bulk GaN semipolar or nonpolar substrate comprising a surface region. The device has an n-type GaN containing layer overlying the surface region. The device has an InGaN active region overlying the surface region. The device has a blue emitting region within a first portion of the InGaN active region and a yellow emitting region within a second portion of the InGaN active region. The device has a p-type GaN containing layer overlying the InGaN active region.

Moreover, in yet an alternative specific embodiment, the present invention provides a light emitting device. The device has a bulk GaN semipolar or nonpolar substrate comprising a surface region. The device has an n-type GaN containing layer overlying the surface region. The device has an InGaN active region overlying the surface region. The device has a blue emitting region within a first portion of the InGaN active region, a green emitting region within a second portion of the InGaN active region, and a red emitting region within a third portion of the InGaN active region. The device further has a p-type GaN containing layer overlying the InGaN active region.

Still further, the present invention provides a light emitting device. The device includes a bulk GaN containing semipolar or nonpolar substrate. The bulk GaN containing semipolar or nonpolar substrate comprises a surface region and a bottom region. The device also has an n-type GaN containing material overlying the surface region, a blue LED device region coupled to the surface region, a green LED device region coupled to the surface region, and a red LED device region coupled to the surface region to form a stacked structure.

Moreover, the present invention provides a light emitting device. The device has a bulk GaN containing semipolar or nonpolar substrate. The bulk GaN containing semipolar or nonpolar substrate comprises a surface region and a bottom region. The device also has an n-type GaN containing material overlying the surface region, a blue LED device region coupled to the surface region, and a yellow LED device region coupled to the blue LED device region to form a stacked structure.

In yet an alternative embodiment, the present invention provides a method for packaged light emitting device. The method includes providing a substrate member comprising a surface region. The substrate member comprises a semipolar or nonpolar GaN containing substrate. The method also includes forming two or more light emitting diode devices overlying the surface region. The two or more light emitting diode devices are fabricated on the semipolar or nonpolar GaN containing substrate providing substantially polarized emission.

In other embodiments, the present invention provides a method of fabricating a monolithic light emitting device. The method includes providing a bulk GaN containing semipolar or nonpolar substrate comprising a surface region. The method also includes forming an n-type GaN containing layer overlying the surface region. In a preferred embodiment, the n-type GaN containing layer has a first region and a second region. The method further includes forming a first LED device region provided on the first region. The first LED device region has a first color characteristic according to one or more embodiments. The method forms a second LED device region provided on the second region. Preferably, the second LED device region has a second color characteristic.

In yet an alternative embodiment, the present invention provides a method of forming monolithic light emitting device. The method includes providing a bulk GaN containing semipolar or nonpolar substrate comprising a surface region. The method also includes forming an n-type GaN containing layer overlying the surface region. In a preferred embodiment, the n-type GaN containing layer has a first region and a second region. The method includes forming a first LED device region provided on the first region, forming a second LED device region provided on the second region, and forming a third LED device region provided on the third region.

In other embodiments, the present invention provides a method of fabricating a light emitting device. The method includes providing a bulk GaN containing semipolar or nonpolar substrate. In a preferred embodiment, the bulk GaN containing semipolar or nonpolar substrate comprises a surface region and a bottom region. The method includes forming an n-type GaN containing material overlying the surface region. The method also includes forming a blue LED device region overlying the surface region and forming a yellow LED device region overlying the blue LED device region to form a stacked structure. In a preferred embodiment, the blue and yellow LED device regions emit in combination white light or the like.

Still further, the present invention provides yet an alternative method of fabricating a light emitting device. The method includes providing a bulk GaN containing semipolar or nonpolar substrate. In a specific embodiment, the bulk GaN containing semipolar or nonpolar substrate comprises a surface region and a bottom region. The method includes forming an n-type GaN containing material overlying the surface region, forming a blue LED device region overlying the surface region, forming a green LED device region overlying the blue LED device region and forming a red LED device region overlying the green LED device region to form a stacked structure.

In yet other embodiments, the present invention provides a method for fabricating a light emitting device. The method includes providing a bulk GaN semipolar or nonpolar substrate comprising a surface region. The method includes forming an n-type GaN containing layer overlying the surface region and forming an InGaN active region overlying the surface region. In a specific embodiment, the method forms a blue emitting region within a first portion of the InGaN active region and a yellow emitting region within a second portion of the InGaN active region. The method also forms a p-type GaN containing layer overlying the InGaN active region. In other embodiments, the method forms a blue emitting region within a first portion of the InGaN active region, a green emitting region within a second portion of the InGaN active region, and a red emitting region within a third portion of the InGaN active region. Of course, there may be other variations, modifications, and alternatives.

In yet other embodiments, the present invention provides a method for fabricating a light emitting device. The method includes providing a bulk GaN containing semipolar or nonpolar substrate. The method includes forming an n-type GaN containing material overlying the surface region. The method forms a blue LED device region coupled to the surface region, a green LED device region coupled to the surface region, and a red LED device region coupled to the surface region to form a stacked structure. In alternative embodiments, the method forms a blue LED device region coupled to the surface region and a yellow LED device region coupled to the blue LED device region to form a stacked structure.

One or more benefits may be achieved using one or more of the specific embodiments. As an example, the present device and method provides for an improved lighting technique with improved efficiencies. In other embodiments, the present method and resulting structure are easier to implement using conventional technologies. In some embodiments, the present device and method provide light at two or more wavelengths that are useful in displays. In a specific embodiment, the device is configured to emit substantially polarized light without filters and the like, although there can also be some variations. Depending upon the embodiment, one or more of these benefits can be achieved. These and other benefits are further described throughout the present specification and more particularly below.

The present invention achieves these benefits and others in the context of known process technology. However, a further understanding of the nature and advantages of the present invention may be realized by reference to the latter portions of the specification and attached drawings. As used herein, the terms “first” “second” or “third” or “n” are not intended to imply order but should be construed under ordinary meaning as one of ordinary skill in the art. Of course, there can be other variations, modifications, and alternatives. Additionally, the terms “blue” “red” “yellow” “green” or other colors are interpreted by ordinary meaning, and not unduly limiting the scope of the claims herein. One of ordinary skill in the art would recognize other variations, modifications, and alternatives. Additionally, any color combination and/or wavelength combination using the techniques described herein are included as well as other variations, modifications, and alternatives, in one or more embodiments. Further details of the present invention are described throughout the present specification and more particularly below.

### BRIEF DESCRIPTION OF THE DRAWINGS

FIG. 1 shows a first embodiment of this invention where FIG. 1A presents copackaged blue and yellow semipolar GaN-based LEDs and FIG. 1B presents copackaged blue, green, and red semipolar GaN-based LEDs according to an embodiment of the present invention.

FIG. 2 shows a second embodiment of this invention where FIG. 2A presents monolithic side-by-side blue and yellow semipolar GaN-based LEDs and FIG. 2B presents monolithic side by side blue, green, and red semipolar GaN-based LEDs according to an embodiment of the present invention.

FIG. 3 shows a third embodiment of this invention where FIG. 3A presents vertically stacked blue and yellow semipolar GaN-based LEDs and FIG. 3B presents vertically stacked blue, green, and red semipolar GaN-based LED emitting regions according to an embodiment of the present invention.

FIG. 4 shows a fourth embodiment of this invention where FIG. 4a presents blue and yellow emitter layers within the same active region of a semipolar GaN-based LED and FIG. 4b presents blue, green, and red emitter layers within the same active region of a semipolar GaN-based LED according to an embodiment of the present invention.

FIG. 5A is a simplified diagram of a conduction band of an RGB active region in phosphorless white LED on semipolar or nonpolar bulk GaN substrates according to an embodiment of the present invention.

FIG. 5B is a simplified diagram of a conduction band of a blue and yellow active region in phosphorless white LED on semipolar or nonpolar bulk GaN substrates according to an embodiment of the present invention.

FIG. 5C is a simplified diagram of a conduction band of an RGB tunnel junction based active region in phosphorless white LED on semipolar or nonpolar bulk GaN substrates according to an embodiment of the present invention.

FIG. 6A illustrates experimental results showing electroluminescence from multi-color active regions according to an embodiment of the present invention.

FIG. 6B illustrates experimental results showing electroluminescence from multi-color active regions according to an embodiment of FIG. 1B of the present invention.

FIG. 7A is a simplified top-side emitting phosphorless white LED on semipolar or nonpolar bulk GaN substrates according to an embodiment of the present invention.

FIG. 7B is a simplified bottom-side emitting phosphorless white LED on semipolar or nonpolar bulk GaN substrates according to an embodiment of the present invention.

FIG. 8 is a chromaticity diagram according to an embodiment of the present invention.

### DETAILED DESCRIPTION OF THE SPECIFIC EMBODIMENTS

According to the present invention, techniques for lighting are provided. More specifically, embodiments of the invention include techniques for combining different colored LED devices, such as blue and yellow, fabricated on bulk semipolar or nonpolar materials. Merely by way of example, the invention can be applied to applications such as white lighting, multi-colored lighting, lighting for flat panels, other optoelectronic devices, and the like.

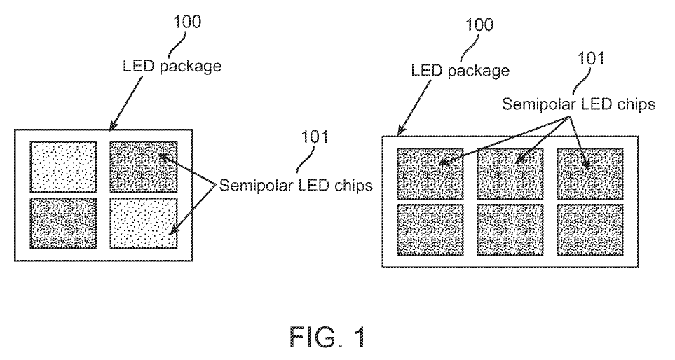

FIG. 1 shows the first embodiment of this invention where FIG. 1A presents copackaged blue and yellow semipolar GaN-based LEDs and FIG. 1B presents copackaged blue, green, and red semipolar GaN-based LEDs. These devices could be wired in series, parallel, or on isolated circuits. In a specific embodiment, the LED package 100 includes a blue and a yellow LED device, which can co-package two or more LED devices 101, as shown. In a specific embodiment, the two or more LED devices can include one or more of each color such as red, blue, green, and others for color rendering. As an example, the two or more LED devices have been described in various publications, noted herein, which have been incorporated by reference, among others. In a preferred embodiment, the LED devices are fabricated on semipolar gallium nitride substrate material, but can be others. Of course, there can be other variations, modifications, and alternatives.

As used herein, the term GaN substrate is associated with Group III-nitride based materials including GaN, InGaN, AlGaN, or other Group III containing alloys or compositions that are used as starting materials. Such starting materials include polar GaN substrates (i.e., substrate where the largest area surface is nominally an (h k l) plane wherein h=k=0, and l is non-zero), non-polar GaN substrates (i.e., substrate material where the largest area surface is oriented at an angle ranging from about 80-100 degrees from the polar orientation described above towards an (h k l) plane wherein l=0, and at least one of h and k is non-zero) or semi-polar GaN substrates (i.e., substrate material where the largest area surface is oriented at an angle ranging from about +0.1 to 80 degrees or 110-179.9 degrees from the polar orientation described above towards an (h k l) plane wherein l=0, and at least one of h and k is non-zero). Of course, there can be other variations, modifications, and alternatives.

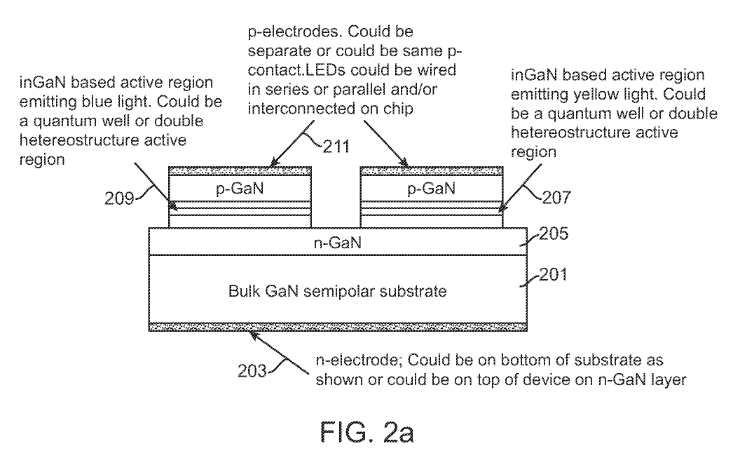

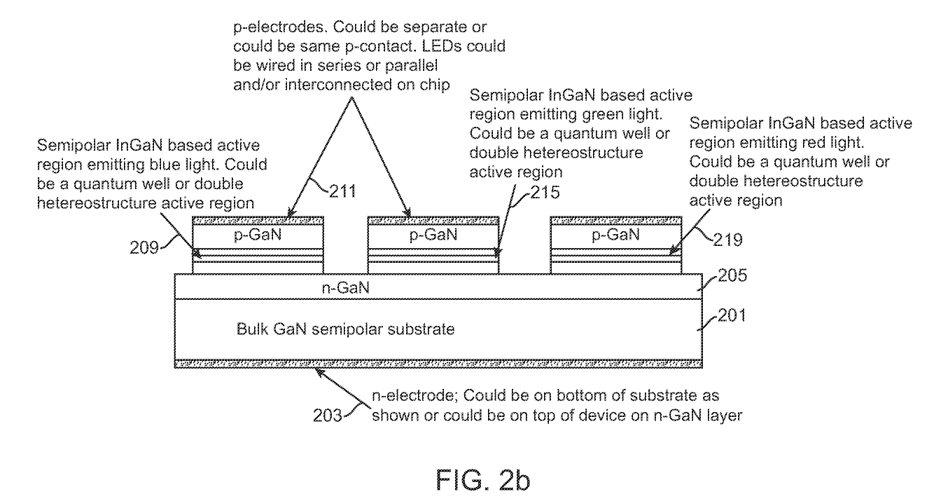

FIG. 2 shows the second embodiment of this invention where FIG. 2A presents monolithic side-by-side blue and yellow semipolar GaN-based LEDs and FIG. 2B presents monolithic side by side blue, green, and red semipolar GaN-based LEDs. These devices could be wired in series, parallel, or on isolated circuits. As shown in FIG. 2A, each of the devices is disposed side by side in a monolithic configuration and disposed on a gallium nitride substrate structure. As shown, the LED devices are formed on bulk gallium nitride semipolar substrate 201, which includes an n-type electrode 203, which may be overlying a bottom region of the substrate. Alternatively, the n-type electrode may be overlying a top region of the substrate overlying an n-type gallium nitride material layer. In a specific embodiment, the n-type electrode is made of suitable materials. In one or more embodiments, the n-type electrode is made of a metal stack, which commonly use Al/Au, Ti/Al/Ni/Au, Al/Pt/Au, or Ti/Al/Pt/Au, among others. In one or more embodiments, the electrode may or may not include an annealing step associated with the electrodes. In one or more embodiments having an anneal, it will typically be between 300-900C in an atmosphere of N2, O2, or N2/O2 for a time ranging from 1 to 30 minutes. Of course, there can be other variations, modifications, and alternatives.

Overlying the bulk GaN substrate is an n-type GaN epitaxial layer. In a specific embodiment, the epitaxial layer is preferably deposited using a MOCVD process and tool, but can be other techniques. The epitaxial layer is high quality and substantially free from defects and other imperfections that would lead to performance degradation. In a specific embodiment, the monolithic structure includes at least a blue LED 209 and a yellow LED 207, among others. In a specific embodiment, the blue LED includes active region, which may include a quantum well or double heterostructure active region, among others. In a specific embodiment, the yellow LED 207 includes active region, which may include a quantum well or double heterostructure active region, among others. In a specific embodiment, each of the LED devices includes a p-type electrode material layer 211, as shown. In a specific embodiment, the p-type electrode material layer is an indium tin oxide, but can be others, such as those described herein as well as outside of the specification. An example of a yellow LED is also illustrated in Sato, et al. of the Materials Department and Electrical and Computer Engineering Department, University of California, Santa Barbara, Calif. 93106 USA, titled “Optical properties of yellow light-emitting diodes grown on semipolar (11-22) bulk GaN substrates,” Applied Physics Letters 92, 221110 (2008), which is incorporated by reference herein. An example of a blue LED is also illustrated in [1] H. Zhong, A. Tyagi, N. N. Fellows, F. Wu, R. B. Chung, M. Saito, K. Fujito, J. S. Speck, S. P. DenBaars, and S. Nakamura, “High power and high efficiency blue light emitting diode on freestanding semipolar (1122) bulk GaN substrate,” Appl. Phys. Lett., vol. 90, 2007, which is incorporated by reference herein, and H. Zhong, et al., titled “High power and high efficiency blue light emitting diode on freestanding semipolar (10-1-1) bulk GaN substrate,” Applied Physics Letters 90, 233504 (2007), which is incorporated by reference herein. Of course, there can be other variations, modifications, and alternatives.

In a specific embodiment, the present invention including methods and structures achieves different colors, respectively, from the different LED regions or more commonly termed different emitting layers. In one or more embodiments, emitting layers are typically quantum wells that are characterized by thicknesses from 1-15 nm, but could also be double hetereostructures that are characterized by thicknesses greater than about 15 nm. In a specific embodiment, it is believed that a transition between a quantum well and a double hetereostructure is not a well defined or hard boundary—it could range from 10 nm to 20 nm.

In both types of emitting layers, the emission wavelength is controlled by at least the indium content within the gallium nitride epitaxial material, and possibly other parameters. In a specific embodiment, the blue region is characterized by about a 10-20% range of mole fraction indium in the gallium nitride epitaxial material. In a specific embodiment, the green region is characterized by about a 20-30% range of mole fraction indium in the gallium nitride epitaxial material. In a specific embodiment, the yellow region is characterized by about the 30-40% range of mole fraction indium in the gallium nitride epitaxial material. In a specific embodiment, the red region is characterized by about +40% range of mole fraction indium in the gallium nitride epitaxial material. In a specific embodiment, the indium content is adjusted selectively from one layer to the next layer by changing the growth temperature to cause change the indium incorporation efficiency and/or by changing the relative ratio of indium to gallium by adding more or less indium precursor or more or less gallium precursor or some combination of both. Of course, there can be other variations, modifications, and alternatives.

In a specific embodiment, the present invention uses a selected thickness for the quantum well to achieve different color emissions for a given or selected indium content. In a specific embodiment, the emission wavelength is controlled by a selected thickness of the quantum well region. In one or more embodiments, thicker quantum wells with the same indium content will often emit at longer wavelengths. In one or more other embodiments, the method and structures use a combination of differing indium and differing quantum well thicknesses to achieve different color emitting layers on the same device structure. As will be further demonstrated below, we have achieved different color emissions by changing indium composition according to one or more embodiments. Of course, there can be other variations, modifications, and alternatives.

In a preferred embodiment, the present method and structure achieves different emission colors by different thicknesses of emitting layers. That is, the method forms different thicknesses of emitting layers by way of either the use of different growth times for the two or more emitting layers given that both of the layers have similar or the same growth rates. Alternatively, the method forms different thicknesses of emitting layers by way of changing the growth rate of the different layers while maintaining the same growth time according to a specific embodiment. In yet other embodiments, the method and structure relies upon a combination of the two techniques, among others. Of course, there can be other variations, modifications, and alternatives.

In one or more embodiments that are free from a tunnel junction, different emitting quantum well layers are placed in the same p-i-n junction such that they share a common p-GaN cladding layer above or below the active region and a common n-GaN cladding layer on the other side. The different emitting layers are separated by barrier layers, which can be GaN, InGaN, AlGaN, or InAlGaN, combinations, and others. In one or more embodiments, including the experimental results noted below, the emitting layers were separated by GaN barriers. Of course, there can be other variations, modifications, and alternatives.

In still further embodiments, the present method and structures can include two or more emitting layers having substantially the same color emission or like emission. Depending upon the embodiment, the two or more emitting layers that have the same emission can be selectively introduced for color balancing and/or the like. Depending upon the embodiment, each of the substantially similar layers can be stacked sequentially or stacked in an arrangement with an intermediary emission layer or layers. Of course, there can be other variations, modifications, and alternatives.

Referring now to FIG. 2B, each of the devices, including blue, red, and green, is disposed side by side in a monolithic configuration and disposed on a gallium nitride substrate structure. As shown, the LED devices are formed on bulk gallium nitride semipolar substrate 201, which includes an n-type electrode 203, which may be overlying a bottom region of the substrate. Alternatively, the n-type electrode may be overlying a top region of the substrate overlying an n-type gallium nitride material layer. In a specific embodiment, the n-type electrode is made of suitable materials. In one or more embodiments, the n-type electrode is made of a metal stack, which commonly use Al/Au, Ti/Al/Ni/Au, Al/Pt/Au, or Ti/Al/Pt/Au, among others. In one or more embodiments, the electrode may or may not include an annealing step associated with the electrodes. In one or more embodiments having an anneal, it will typically be between 300-900C in an atmosphere of N2, O2, or N2/O2 for a time ranging from 1 to 30 minutes. Of course, there can be other variations, modifications, and alternatives.

Overlying the bulk GaN substrate is an n-type GaN epitaxial layer 205. In a specific embodiment, the epitaxial layer is preferably deposited using a MOCVD process and tool, but can be other techniques. The epitaxial layer is high quality and substantially free from defects and other imperfections that would lead to performance degradation. In a specific embodiment, the epitaxial layer includes at least a blue LED 209, a green LED 215, and a red LED 219, among others. In a specific embodiment, the blue LED includes active region, which may include a quantum well or double heterostructure active region, among others. In a specific embodiment, the green LED 215 includes active region, which may include a quantum well or double heterostructure active region, among others. In a specific embodiment, the red LED 219 includes active region, which may include a quantum well or double heterostructure active region, among others.

In a specific embodiment, the present invention including methods and structures achieves different colors, respectively, from the different LED regions or more commonly termed different emitting layers. In one or more embodiments, emitting layers are typically quantum wells that are characterized by thicknesses from 1-15 nm, but could also be double hetereostructures that are characterized by thicknesses greater than about 15 nm. In a specific embodiment, it is believed that a transition between a quantum well and a double hetereostructure is not a well defined or hard boundary—it could range from 10 nm to 20 nm.

In both types of emitting layers, the emission wavelength is controlled by at least the indium content within the gallium nitride epitaxial material, and possibly other parameters. In a specific embodiment, the blue region is characterized by about a 10-20% range of mole fraction indium in the gallium nitride epitaxial material. In a specific embodiment, the green region is characterized by about a 20-30% range of mole fraction indium in the gallium nitride epitaxial material. In a specific embodiment, the yellow region is characterized by about the 30-40% range of mole fraction indium in the gallium nitride epitaxial material. In a specific embodiment, the red region is characterized by about +40% range of mole fraction indium in the gallium nitride epitaxial material. In a specific embodiment, the indium content is adjusted selectively from one layer to the next layer by changing the growth temperature to cause change the indium incorporation efficiency and/or by changing the relative ratio of indium to gallium by adding more or less indium precursor or more or less gallium precursor or some combination of both. Of course, there can be other variations, modifications, and alternatives.

In a specific embodiment, the present invention uses a selected thickness for the quantum well to achieve different color emissions for a given or selected indium content. In a specific embodiment, the emission wavelength is controlled by a selected thickness of the quantum well region. In one or more embodiments, thicker quantum wells with the same indium content will often emit at longer wavelengths. In one or more other embodiments, the method and structures use a combination of differing indium and differing quantum well thicknesses to achieve different color emitting layers on the same device structure. As will be further demonstrated below, we have achieved different color emissions by changing indium composition according to one or more embodiments. Of course, there can be other variations, modifications, and alternatives.

In a preferred embodiment, the present method and structure achieves different emission colors by different thicknesses of emitting layers. That is, the method forms different thicknesses of emitting layers by way of either the use of different growth times for the two or more emitting layers given that both of the layers have similar or the same growth rates. Alternatively, the method forms different thicknesses of emitting layers by way of changing the growth rate of the different layers while maintaining the same growth time according to a specific embodiment. In yet other embodiments, the method and structure relies upon a combination of the two techniques, among others. Of course, there can be other variations, modifications, and alternatives.

In one or more embodiments that are free from a tunnel junction, different emitting quantum well layers are placed in the same p-i-n junction such that they share a common p-GaN cladding layer above or below the active region and a common n-GaN cladding layer on the other side. The different emitting layers are separated by barrier layers, which can be GaN, InGaN, AlGaN, or InAlGaN, combinations, and others. In one or more embodiments, including the experimental results noted below, the emitting layers were separated by GaN barriers. Of course, there can be other variations, modifications, and alternatives.

In still further embodiments, the present method and structures can include two or more emitting layers having substantially the same color emission or like emission. Depending upon the embodiment, the two or more emitting layers that have the same emission can be selectively introduced for color balancing and/or the like. Depending upon the embodiment, each of the substantially similar layers can be stacked sequentially or stacked in an arrangement with an intermediary emission layer or layers. Of course, there can be other variations, modifications, and alternatives.

In a specific embodiment, each of the LED devices includes a p-type electrode material layer 211, as shown. In a specific embodiment, the p-type electrode material layer is a transparent conductor, but can be others. As an example, Indium Tin Oxide (ITO) is a transparent conductive oxide that simultaneously serves a p-contact and current spreading layer in ITO-based topside emitting LEDs. In a specific embodiment, the ITO is typically improved and/or optimized with respect to transparency, sheet resistance, and specific contact resistance. To reduce interface reflections back into the device, the thickness of the ITO is typically tailored to be an odd multiple of a quarter optical wavelength in the material (i.e.—t=n*lambda/4 where n=1, 3, 5 . . . ). In a specific embodiment, the ITO is often used as a more transparent substitute for conventional semi-transparent current spreading layers, such as thin Ni/Au or thin Pd/Au. Of course, there can be other variations, modifications, and alternatives. Of course, there can be other variations, modifications, and alternatives.

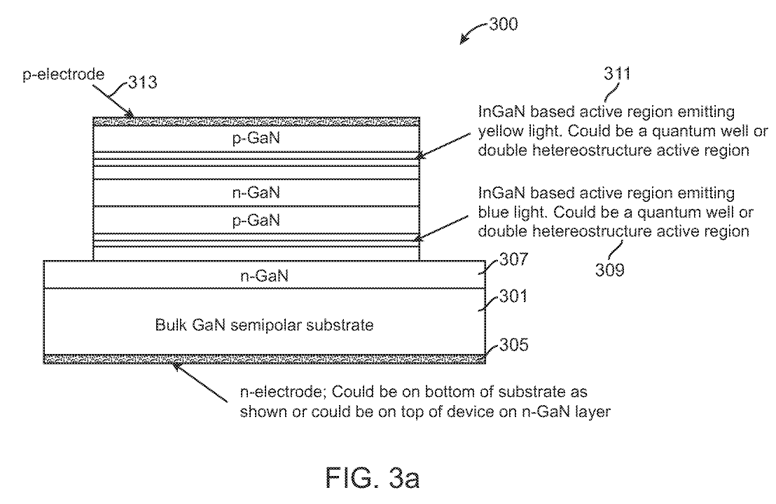

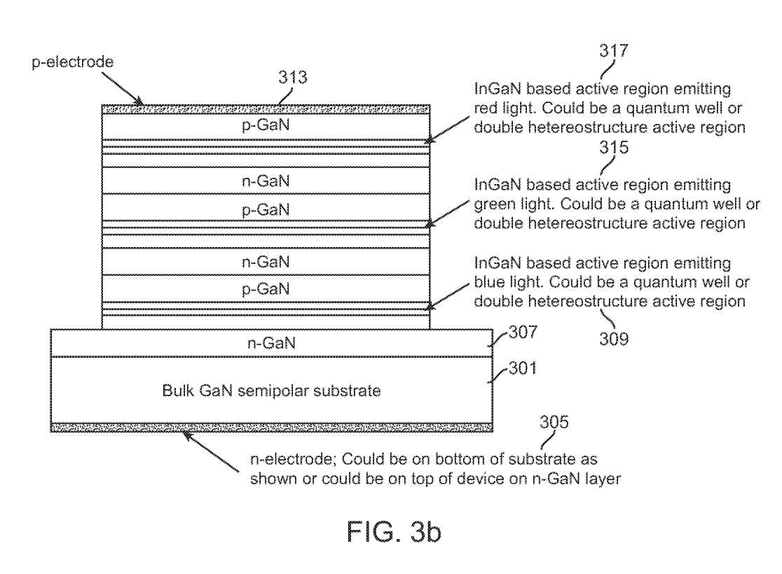

FIG. 3 shows the third embodiment of this invention where FIG. 3A presents vertically stacked blue and yellow semipolar GaN-based LEDs and FIG. 3B presents vertically stacked blue, green, and red semipolar GaN-based LED emitting regions. From a growth standpoint, this embodiment would likely be the most practical with the shorter wavelength emitter regions being on the bottom of the stack and then capturing the light out of the bottom of the device. However, there could be other arrangements making use of different stacking configurations. This configuration would use tunnel junctions positioned between the different emitting regions.

Referring to FIG. 3A, the vertically stacked blue yellow LED includes LED devices configured in a vertical arrangement on a gallium nitride substrate structure. As shown, the LED devices are formed on bulk gallium nitride semipolar substrate 301, which includes an n-type electrode 305, which may be overlying a bottom region of the substrate. Alternatively, the n-type electrode may be overlying a top region of the substrate overlying an n-type gallium nitride material layer. In a specific embodiment, the n-type electrode is made of suitable materials. In one or more embodiments, the n-type electrode is made of a metal stack, which commonly use Al/Au, Ti/Al/Ni/Au, Al/Pt/Au, or Ti/Al/Pt/Au, among others. In one or more embodiments, the electrode may or may not include an annealing step associated with the electrodes. In one or more embodiments having an anneal, it will typically be between 300-900C in an atmosphere of N2, O2, or N2/O2 for a time ranging from 1 to 30 minutes. Of course, there can be other variations, modifications, and alternatives.

Overlying the bulk GaN substrate is an n-type GaN epitaxial layer 307. In a specific embodiment, the epitaxial layer is preferably deposited using a MOCVD process and tool, but can be other techniques. The epitaxial layer is high quality and substantially free from defects and other imperfections that would lead to performance degradation. In a specific embodiment, the vertical stacked device includes at least a blue LED 309 and a yellow LED 311, among others. In a specific embodiment, the blue LED includes active region, which may include a quantum well or double heterostructure active region, among others. In a specific embodiment, the yellow LED, which is overlying the blue LED, includes active region, which may include a quantum well or double heterostructure active region, among others. In a specific embodiment, the top LED device, which is for example yellow, includes a p-type electrode material layer 313, as shown. In a specific embodiment, the p-type electrode material layer is an indium tin oxide, but can be others, such as those described herein as well as outside of the specification. Of course, there can be other variations, modifications, and alternatives.

Referring now to FIG. 3B, the vertically stacked blue green red LED includes LED devices configured in a vertical arrangement on a gallium nitride substrate structure. As shown, the LED devices are formed on bulk gallium nitride semipolar substrate 301, which includes an n-type electrode 305, which may be overlying a bottom region of the substrate. Alternatively, the n-type electrode may be overlying a top region of the substrate overlying an n-type gallium nitride material layer. In a specific embodiment, the n-type electrode is made of suitable materials. In one or more embodiments, the n-type electrode is made of a metal stack, which commonly use Al/Au, Ti/Al/Ni/Au, Al/Pt/Au, or Ti/Al/Pt/Au, among others. In one or more embodiments, the electrode may or may not include an annealing step associated with the electrodes. In one or more embodiments having an anneal, it will typically be between 300-900C in an atmosphere of N2, O2, or N2/O2 for a time ranging from 1 to 30 minutes. Of course, there can be other variations, modifications, and alternatives.

Overlying the bulk GaN substrate is an n-type GaN epitaxial layer 307. In a specific embodiment, the epitaxial layer is preferably deposited using a MOCVD process and tool, but can be other techniques. The epitaxial layer is high quality and substantially free from defects and other imperfections that would lead to performance degradation. In a specific embodiment, the vertical stacked device includes at least a blue LED 309, a green LED 315, and a red LED 317, among others. In a specific embodiment, the blue LED includes active region, which may include a quantum well or double heterostructure active region, among others. In a specific embodiment, the green LED, which is overlying the blue LED, includes active region, which may include a quantum well or double heterostructure active region, among others. In a specific embodiment, the red LED, which is overlying the green LED, includes active region, which may include a quantum well or double heterostructure active region, among others. In a specific embodiment, the top LED device region, which is for example red, includes a p-type electrode material layer 313, as shown. In a specific embodiment, the p-type electrode material layer is an indium tin oxide, but can be others, such as those described herein as well as outside of the specification. Of course, there can be other variations, modifications, and alternatives.

In a specific embodiment, the present invention including methods and structures achieves different colors, respectively, from the different LED regions or more commonly termed different emitting layers. In one or more embodiments, emitting layers are typically quantum wells that are characterized by thicknesses from 1-15 nm, but could also be double hetereostructures that are characterized by thicknesses greater than about 15 nm. In a specific embodiment, it is believed that a transition between a quantum well and a double hetereostructure is not a well defined or hard boundary—it could range from 10 nm to 20 nm. In both types of emitting layers, the emission wavelength is controlled by at least the indium content within the gallium nitride epitaxial material, and possibly other parameters. In a specific embodiment, the blue region is characterized by about a 10-20% range of mole fraction indium in the gallium nitride epitaxial material. In a specific embodiment, the green region is characterized by about a 20-30% range of mole fraction indium in the gallium nitride epitaxial material. In a specific embodiment, the yellow region is characterized by about the 30-40% range of mole fraction indium in the gallium nitride epitaxial material. In a specific embodiment, the red region is characterized by about +40% range of mole fraction indium in the gallium nitride epitaxial material. In a specific embodiment, the indium content is adjusted selectively from one layer to the next layer by changing the growth temperature to cause change the indium incorporation efficiency and/or by changing the relative ratio of indium to gallium by adding more or less indium precursor or more or less gallium precursor or some combination of both. Of course, there can be other variations, modifications, and alternatives.

In a specific embodiment, the present invention uses a selected thickness for the quantum well to achieve different color emissions for a given or selected indium content. In a specific embodiment, the emission wavelength is controlled by a selected thickness of the quantum well region. In one or more embodiments, thicker quantum wells with the same indium content will often emit at longer wavelengths. In one or more other embodiments, the method and structures use a combination of differing indium and differing quantum well thicknesses to achieve different color emitting layers on the same device structure. As will be further demonstrated below, we have achieved different color emissions by changing indium composition according to one or more embodiments. Of course, there can be other variations, modifications, and alternatives.

In a preferred embodiment, the present method and structure achieves different emission colors by different thicknesses of emitting layers. That is, the method forms different thicknesses of emitting layers by way of either the use of different growth times for the two or more emitting layers given that both of the layers have similar or the same growth rates. Alternatively, the method forms different thicknesses of emitting layers by way of changing the growth rate of the different layers while maintaining the same growth time according to a specific embodiment. In yet other embodiments, the method and structure relies upon a combination of the two techniques, among others. Of course, there can be other variations, modifications, and alternatives.

In one or more embodiments that are free from a tunnel junction, different emitting quantum well layers are placed in the same p-i-n junction such that they share a common p-GaN cladding layer above or below the active region and a common n-GaN cladding layer on the other side. The different emitting layers are separated by barrier layers, which can be GaN, InGaN, AlGaN, or InAlGaN, combinations, and others. In one or more embodiments, including the experimental results noted below, the emitting layers were separated by GaN barriers. Of course, there can be other variations, modifications, and alternatives.

In still further embodiments, the present method and structures can include two or more emitting layers having substantially the same color emission or like emission. Depending upon the embodiment, the two or more emitting layers that have the same emission can be selectively introduced for color balancing and/or the like. Depending upon the embodiment, each of the substantially similar layers can be stacked sequentially or stacked in an arrangement with an intermediary emission layer or layers. Of course, there can be other variations, modifications, and alternatives.

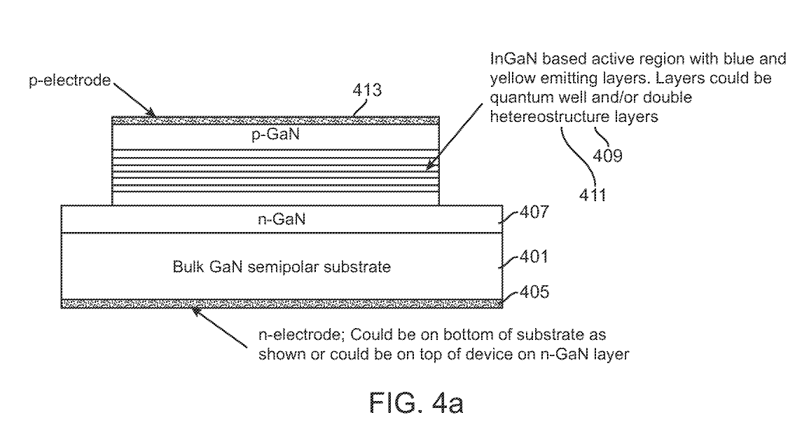

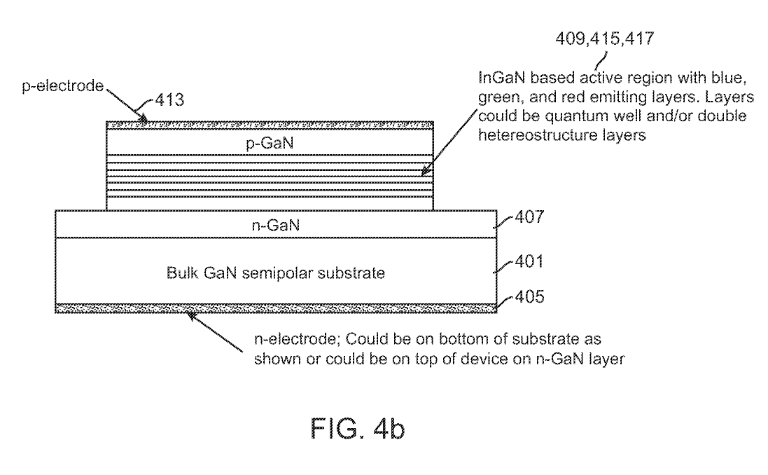

FIG. 4 shows the fourth embodiment of this invention where FIG. 4A presents blue and yellow emitter layers within the same active region of a semipolar GaN-based LED and

FIG. 4B presents blue, green, and red emitter layers within the same active region of a semipolar GaN-based LED. From an epitaxial growth standpoint, this embodiment would likely be the most practical with the shorter wavelength emitter layers positioned in the bottom portion of the active region and then capturing the light out of the bottom of the device. However, there could be other arrangements making use of different stacking configurations. This configuration would not require tunnel junctions between the different emitting regions.

Referring to FIG. 4A, the vertically stacked blue yellow LED includes LED active regions using InGaN configured in a vertical arrangement on a gallium nitride substrate structure. As shown, the LED regions are formed on bulk gallium nitride semipolar substrate 401, which includes an n-type electrode 405, which may be overlying a bottom region of the substrate. Alternatively, the n-type electrode may be overlying a top region of the substrate overlying an n-type gallium nitride material layer. In a specific embodiment, the n-type electrode is made of suitable materials. In one or more embodiments, the n-type electrode is made of a metal stack, which commonly use Al/Au, Ti/Al/Ni/Au, Al/Pt/Au, or Ti/Al/Pt/Au, among others. In one or more embodiments, the electrode may or may not include an annealing step associated with the electrodes. In one or more embodiments having an anneal, it will typically be between 300-900C in an atmosphere of N2, O2, or N2/O2 for a time ranging from 1 to 30 minutes. Of course, there can be other variations, modifications, and alternatives.

Overlying the bulk GaN substrate is an n-type GaN epitaxial layer 407. In a specific embodiment, the epitaxial layer is preferably deposited using a MOCVD process and tool, but can be other techniques. The epitaxial layer is high quality and substantially free from defects and other imperfections that would lead to performance degradation. In a specific embodiment, the vertical stacked device includes at least a blue LED region 409 and a yellow LED region 411, among others. In a specific embodiment, the blue LED active region may include a quantum well or double heterostructure active region, among others. In a specific embodiment, the yellow LED active region, which is overlying the blue LED active region, may include a quantum well or double heterostructure active region, among others. In a specific embodiment, the top LED device region, which is for example yellow, includes a p-type electrode material layer 413, as shown. In a specific embodiment, the p-type electrode material layer is an indium tin oxide, but can be others, such as those described herein as well as outside of the specification. Of course, there can be other variations, modifications, and alternatives.

Referring now to FIG. 4B, the vertically stacked blue green red LED structure includes LED active regions configured in a vertical arrangement on a gallium nitride substrate structure. As shown, the LED device regions are formed on bulk gallium nitride semipolar substrate 401, which includes an n-type electrode 405, which may be overlying a bottom region of the substrate. Alternatively, the n-type electrode may be overlying a top region of the substrate overlying an n-type gallium nitride material layer. In a specific embodiment, the n-type electrode is made of suitable materials. In one or more embodiments, the n-type electrode is made of a metal stack, which commonly use Al/Au, Ti/Al/Ni/Au, Al/Pt/Au, or Ti/Al/Pt/Au, among others. In one or more embodiments, the electrode may or may not include an annealing step associated with the electrodes. In one or more embodiments having an anneal, it will typically be between 300-900C in an atmosphere of N2, O2, or N2/O2 for a time ranging from 1 to 30 minutes. Of course, there can be other variations, modifications, and alternatives.

Overlying the bulk GaN substrate is an n-type GaN epitaxial layer 407. In a specific embodiment, the epitaxial layer is preferably deposited using a MOCVD process and tool, but can be other techniques. The epitaxial layer is high quality and substantially free from defects and other imperfections that would lead to performance degradation. In a specific embodiment, the vertical stacked device includes at least a blue LED region 409, a green LED region 415, and a red LED region 417, among others. In a specific embodiment, the blue LED active region may include a quantum well or double heterostructure active region, among others. In a specific embodiment, the green LED active region, which is overlying the blue LED active region, may include a quantum well or double heterostructure active region, among others. In a specific embodiment, the red LED active region, which is overlying the green LED active region, includes may include a quantum well or double heterostructure active region, among others. In a specific embodiment, the top LED device region, which is for example red, includes a p-type electrode material layer 413, as shown. In a specific embodiment, the p-type electrode material layer is an indium tin oxide, but can be others, such as those described herein as well as outside of the specification. Of course, there can be other variations, modifications, and alternatives.

In a specific embodiment, the present invention including methods and structures achieves different colors, respectively, from the different LED regions or more commonly termed different emitting layers. In one or more embodiments, emitting layers are typically quantum wells that are characterized by thicknesses from 1-15 nm, but could also be double hetereostructures that are characterized by thicknesses greater than about 15 nm. In a specific embodiment, it is believed that a transition between a quantum well and a double hetereostructure is not a well defined or hard boundary—it could range from 10 nm to 20 nm.

In both types of emitting layers, the emission wavelength is controlled by at least the indium content within the gallium nitride epitaxial material, and possibly other parameters. In a specific embodiment, the blue region is characterized by about a 10-20% range of mole fraction indium in the gallium nitride epitaxial material. In a specific embodiment, the green region is characterized by about a 20-30% range of mole fraction indium in the gallium nitride epitaxial material. In a specific embodiment, the yellow region is characterized by about the 30-40% range of mole fraction indium in the gallium nitride epitaxial material. In a specific embodiment, the red region is characterized by about +40% range of mole fraction indium in the gallium nitride epitaxial material. In a specific embodiment, the indium content is adjusted selectively from one layer to the next layer by changing the growth temperature to cause change the indium incorporation efficiency and/or by changing the relative ratio of indium to gallium by adding more or less indium precursor or more or less gallium precursor or some combination of both. Of course, there can be other variations, modifications, and alternatives.

In a specific embodiment, the present invention uses a selected thickness for the quantum well to achieve different color emissions for a given or selected indium content. In a specific embodiment, the emission wavelength is controlled by a selected thickness of the quantum well region. In one or more embodiments, thicker quantum wells with the same indium content will often emit at longer wavelengths. In one or more other embodiments, the method and structures use a combination of differing indium and differing quantum well thicknesses to achieve different color emitting layers on the same device structure. As will be further demonstrated below, we have achieved different color emissions by changing indium composition according to one or more embodiments. Of course, there can be other variations, modifications, and alternatives.

In a preferred embodiment, the present method and structure achieves different emission colors by different thicknesses of emitting layers. That is, the method forms different thicknesses of emitting layers by way of either the use of different growth times for the two or more emitting layers given that both of the layers have similar or the same growth rates. Alternatively, the method forms different thicknesses of emitting layers by way of changing the growth rate of the different layers while maintaining the same growth time according to a specific embodiment. In yet other embodiments, the method and structure relies upon a combination of the two techniques, among others. Of course, there can be other variations, modifications, and alternatives.

In one or more embodiments that are free from a tunnel junction, different emitting quantum well layers are placed in the same p-i-n junction such that they share a common p-GaN cladding layer above or below the active region and a common n-GaN cladding layer on the other side. The different emitting layers are separated by barrier layers, which can be GaN, InGaN, AlGaN, or InAlGaN, combinations, and others. In one or more embodiments, including the experimental results noted below, the emitting layers were separated by GaN barriers. Of course, there can be other variations, modifications, and alternatives.

In still further embodiments, the present method and structures can include two or more emitting layers having substantially the same color emission or like emission. Depending upon the embodiment, the two or more emitting layers that have the same emission can be selectively introduced for color balancing and/or the like. Depending upon the embodiment, each of the substantially similar layers can be stacked sequentially or stacked in an arrangement with an intermediary emission layer or layers. Of course, there can be other variations, modifications, and alternatives.

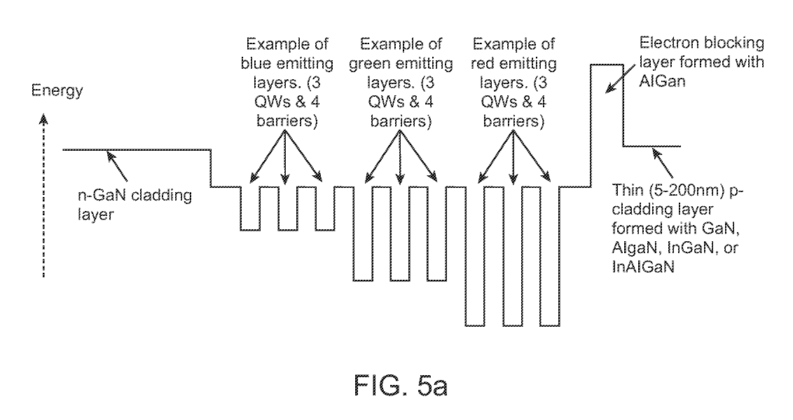

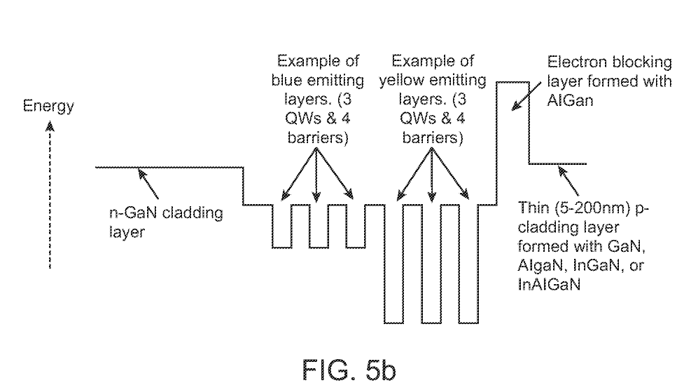

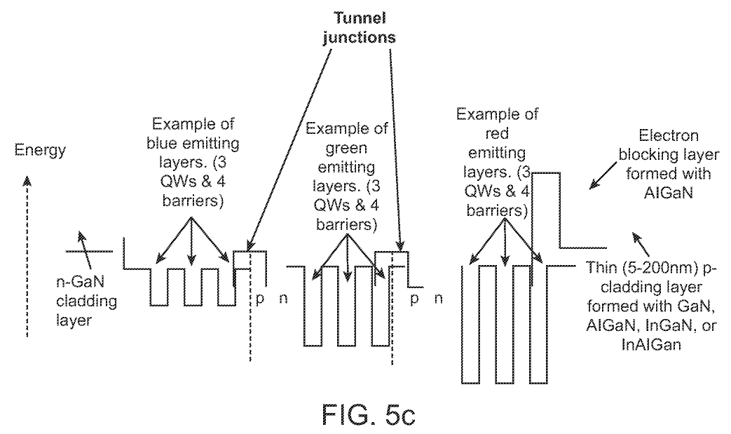

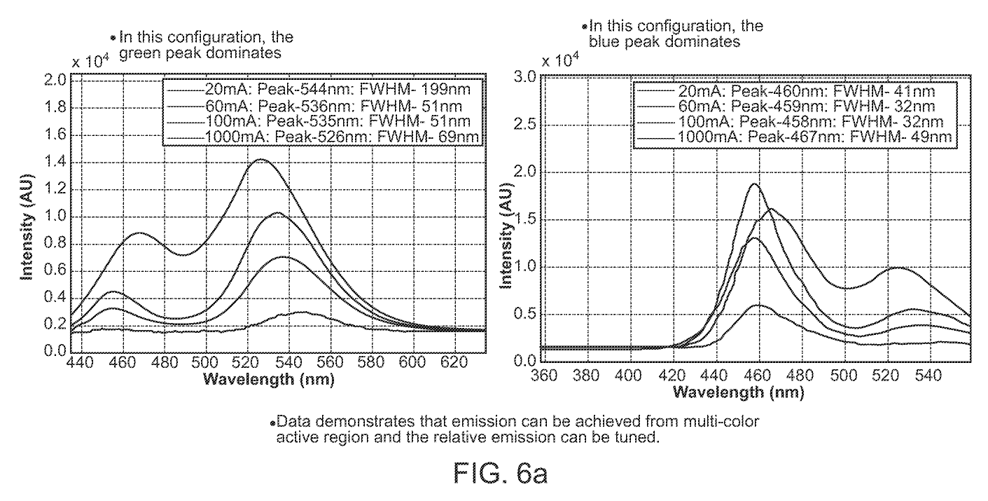

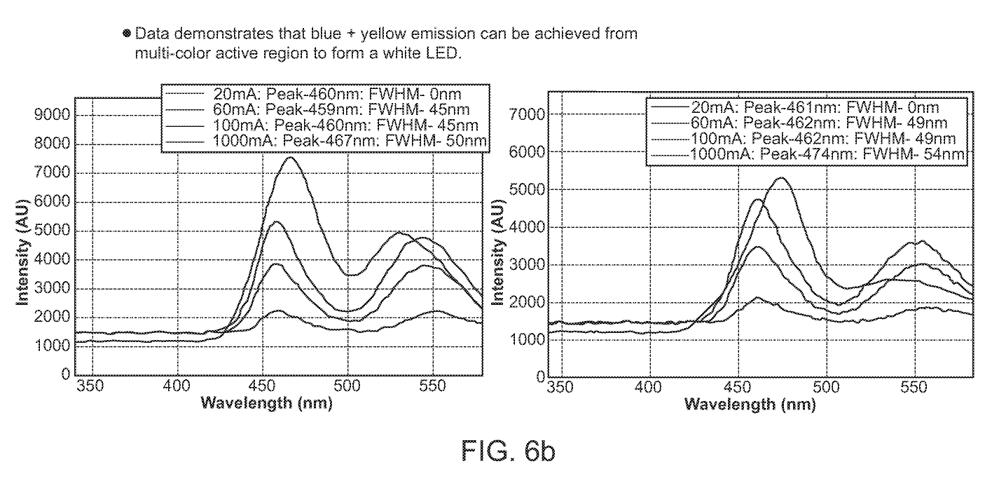

In a specific embodiment, the present invention includes a single growth epitaxial structure containing active layers that emit red, green, and blue radiation, or red, green, yellow, and blue radiation, or blue and yellow radiation from the same layer or similar layer stack resulting in white light emission. The epitaxial structure is fabricated into an LED that emits white light without the need for a phosphor. See, for example, FIGS. 5A, 5B, and 5C and FIGS. 6A and 6B. Of course, there can be other variations, modifications, and alternatives.

In a specific embodiment, the light emitting layers are formed from InGaN in which the indium content substantially influences the emission wavelength, although there may be other factors, as shown in FIGS. 5A and 5B, as examples. As shown, FIG. 5A shows an example of conduction band of RGB active region in phosphorless white light LED on a semipolar or non-polar bulk GaN substrate according to a specific embodiment. As shown, FIG. 5B shows an example of conduction band of blue and yellow active regions in phosphorless white light LED on a semipolar or non-polar bulk GaN substrate according to a specific embodiment. The InGaN light emitting layers may be quantum wells separated by quantum barriers or may be double hetereostructures type emitting layers according to one or more embodiments. Also shown are an n-type GaN cladding layer, which is on a first side of the quantum wells, and an electron blocking layer made of AlGaN material, which is on a second side of the quantum wells. The conduction band also includes a p-type cladding layer having a thickness ranging from about 5 to 20 micrometers overlying the electron blocking layer according to a specific embodiment. Of course, there can be other variations, modifications, and alternatives.

The emitting layers can be contained within the same p-i-n junction such that adjacent layers can be emitting different colors in a specific embodiment. Such a configuration would lead to an improved or ideal diode turn-on voltage equal to the largest band gap of the emitting layers. In order to balance the color characteristics of the integrated emission, careful design of the active region would be desirable. Design aspects would include thickness and number of the emitting layers generating the various colors, the distance the light generating layers are separated from one another, i.e., the barrier thicknesses), the arrangement of the emitting layers, and the addition of doping species to various layers in the active region. For example, in general InGaN layers emitting in the blue region tend to emit more light for a given current than InGaN layers emitting in the green, yellow, or red regions. In one or more embodiments, the present device structure and method uses an increase the number of emitting layers in the green, yellow, and red relative to blue to help balance the color.

In a separate embodiment regions containing the emitting layers could be coupled together with tunnel junctions, as referenced in FIG. 5C. Such a configuration would offer an ideal turn-on voltage equal to the sum of the band gap voltages of the different emitting regions, but may offer better light emission properties since carrier filling of the emitting layers may be more uniform. Design aspects would include thickness and number of the emitting layers generating the various colors, the distance the light generating layers are separated from one another, i.e., the barrier thicknesses), the arrangement of the emitting layers, and the addition of doping species to various layers in the active region. Layers to prevent electron overflow from the light emitting regions such as AlGaN electron blocking layers can be inserted into the structures with various compositions, doping, and thickness according to a specific embodiment.

The epitaxial device structure would use a thin (5-200 nm) p-cladding region grown on top of the emitting regions in one or more embodiments. In a preferred embodiment, thin or ultra-thin layers in the range of 5-50 nm grown at temperatures equal to or slightly hotter than the growth temperature used for the light emitting layers would mitigate degradation to the light emitting layers while offering low resistance to current injected into the LED emitting layers. Conducting oxide layers such as indium-tin-oxide (ITO) or zinc oxide (ZnO) would then be deposited directly in contact with the think p-cladding layer according to one or more embodiments. These conducting oxide layers can be deposited at a lower temperature relative to typical p-GaN growth conditions, and may therefore allow for the formation of a p-contact layer that results in ohmic or quasi-ohmic characteristics, at temperatures which would mitigate degradation of the light emitting layers in one or more embodiments. Additionally, the conducting oxide layers can have optical absorption coefficients at the wavelength ranges of interest which are lower or significantly lower than the optical absorption coefficient of a typical highly doped p-type GaN contact layer, and may therefore help to reduce absorption of emitted light within the device structure. In an alternative embodiment, metallic layers such as silver may be used in place of conducting oxide layers, among other materials or combination of materials. Of course, there can be other variations, modifications, and alternatives.

To prove the principles and operation of one or more of the embodiments, we have provided experimental data, as shown in FIGS. 6A and 6B. Of course, the data are merely examples, which should not unduly limit the scope of the claims herein. One of ordinary skill in the art would recognize variations, modifications, and alternatives. As shown, FIG. 6A illustrates a proof of concept experimental results showing electroluminescence of multi-color active regions having 450 nm and 520 nm (blue and green) emission. The results used a structure similar to those of FIG. 4, as an example. That is, the active region is essentially a single epitaxial growth including at least two color regions, such as blue and green. As shown, the left hand side diagram illustrates the green peak dominates, and simultaneously, the right hand side diagram illustrates the blue peak dominates according to one or more embodiments. As shown, the data in the diagrams demonstrate that emission can be achieved from a multi-color active region and the relative emission can be selectively tuned, using the techniques described herein. Of course, there can be other variations, modifications, and alternatives.

As shown, FIG. 6B illustrates a proof of concept experimental results showing electroluminescence of multi-color active regions having 460 nm and 550 nm (blue and near yellow or yellow) emission. The results used a structure similar to those of FIGS. 4 and 5B, as an example. That is, the active region is essentially a single epitaxial growth including at least two color regions, such as blue and green. As shown, the left hand side and right hand side diagrams illustrate the blue and yellow peaks according to one or more embodiments. As shown, the data in the diagrams demonstrate that emission can be achieved from a multi-color active region and the relative emission can be selectively tuned, using the techniques described herein. Of course, there can be other variations, modifications, and alternatives.

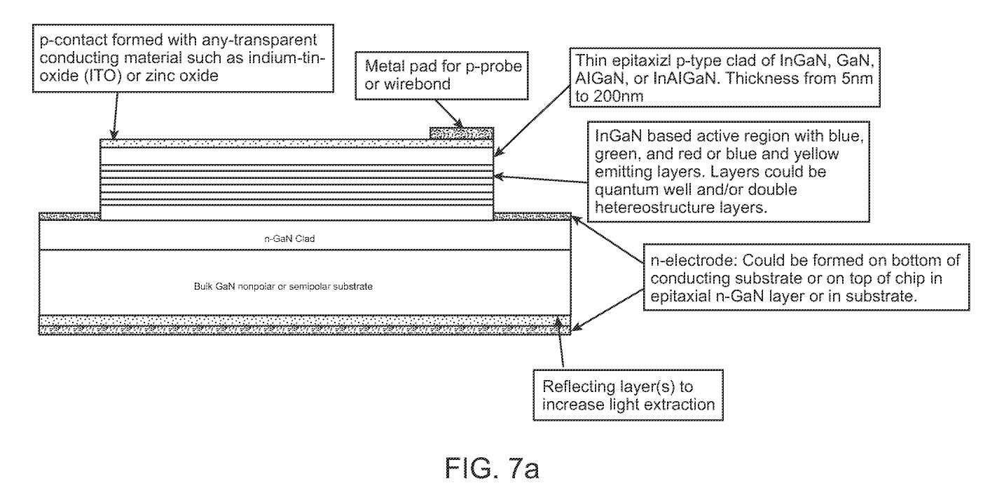

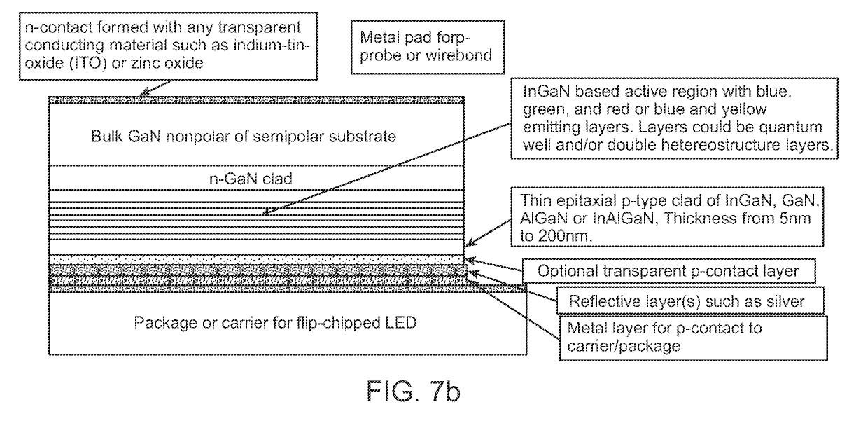

In a specific embodiment, the present invention provides a device having a top-side emitting LED, as illustrated by way of FIG. 7A. In this case a transparent conducting material such as indium-tin-oxide (ITO) or zinc oxide (ZnO) would be used as the p-electrode. This contact would offer low voltage and low absorption loss to the emitted light. This device would contain some sort of reflector on the bottom of the chip to reflected downward emitted light back up through the topside to increase light extraction. The device may have a vertical electrical conduction path (one top-side p-contact and one bottom-side n-contact) or a lateral electrical conduction path (two top-side contacts). The reflector layer may be formed on the bottom of the chip, or may be formed on the sub mount to which the chip is attached. In this latter case, the chip is attached to the sub mount using a die-attach silicone or epoxy which is optically transparent at the wavelength range of interest. The reflector layer may be metallic, or may be formed of a multi-layer dielectric stack. Further, the top and/or bottom surface of the device as well as the edges of the device may be suitably textured or roughened in order to increase light extraction from the chip. The thickness and lateral dimensions of the chip may be suitably chosen so as to minimize absorption of the emitted light and to enhance extraction. Of course, there can be other variations, modifications, and alternatives.

In an alternative embodiment, the present invention provides a bottom-side emitting LED in which the LED chip is flipped and mounted with p-side down, as illustrated by way of FIG. 7B. In this case, a transparent conducting material such as indium-tin-oxide (ITO) or zinc oxide (ZnO) may be used as the p-electrode, and a suitable reflector may be placed adjacent to this layer in order to reflect downward emitted light back up through the topside to increase light extraction. In an alternative embodiment, a metallic reflector layer may be placed in direct contact with the p-type semiconductor layer to form a low voltage contact. The device may have a vertical electrical conduction path (one top-side n-contact and one large-area bottom-side p-contact) or a lateral electrical conduction path (two bottom-side contacts). Further, the top and/or bottom surface of the device as well as the edges of the device may be suitably textured or roughened in order to increase light extraction from the chip. The thickness and lateral dimensions of the chip may be suitably chose so as to minimize absorption of the emitted light and to enhance extraction. Of course, there can be other variations, modifications, and alternatives.

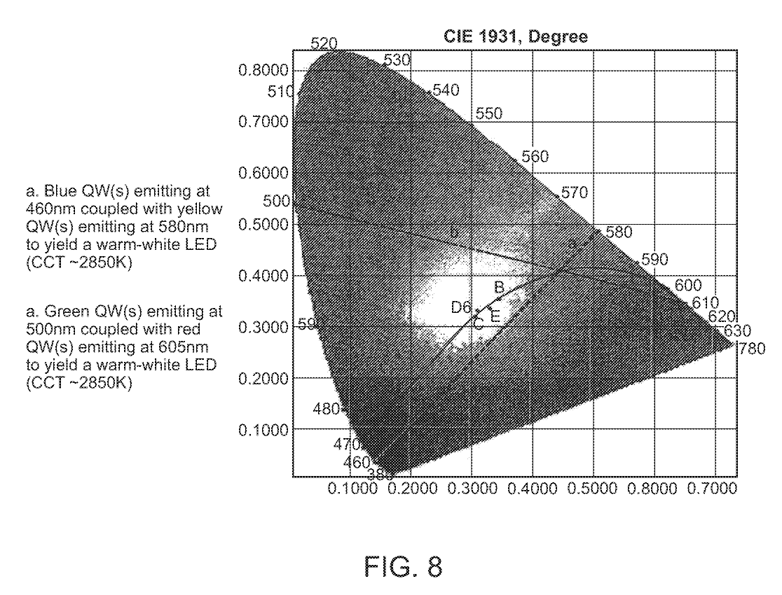

FIG. 8 is a chromaticity diagram according to an embodiment of the present invention. As shown, the diagram is a Commission of Illumination (CIE) chromaticity diagram including tie lines, including, as an example, a loci of phosphorous free white LEDs, although there may be embodiments including phosphor according to other embodiments. As shown, the reference letter “a” shows blue quantum wells emitting at 460 nm coupled with yellow quantum wells emitting at 580 nm to yield a warm white LED (CCT about 2850K), which demonstrates the white LED using yellow and blue. The reference letter “b” shows green quantum wells emitting at 500 nm coupled with red quantum wells emitting at 605 nm to yield a warm white LED. Of course, there may also be variations, modifications, and alternatives.

As noted, in a specific embodiment, the present invention including methods and structures achieves different colors, respectively, from the different LED regions or more commonly termed different emitting layers. In one or more embodiments, emitting layers are typically quantum wells that are characterized by thicknesses from 1-15 nm, but could also be double hetereostructures that are characterized by thicknesses greater than about 15 nm. In a specific embodiment, it is believed that a transition between a quantum well and a double hetereostructure is not a well defined or hard boundary—it could range from 10 nm to 20 nm.

In both types of emitting layers, the emission wavelength is controlled by at least the indium content within the gallium nitride epitaxial material, and possibly other parameters. In a specific embodiment, the blue region is characterized by about a 10-20% range of mole fraction indium in the gallium nitride epitaxial material. In a specific embodiment, the green region is characterized by about a 20-30% range of mole fraction indium in the gallium nitride epitaxial material. In a specific embodiment, the yellow region is characterized by about the 30-40% range of mole fraction indium in the gallium nitride epitaxial material. In a specific embodiment, the red region is characterized by about +40% range of mole fraction indium in the gallium nitride epitaxial material. In a specific embodiment, the indium content is adjusted selectively from one layer to the next layer by changing the growth temperature to cause change the indium incorporation efficiency and/or by changing the relative ratio of indium to gallium by adding more or less indium precursor or more or less gallium precursor or some combination of both. Of course, there can be other variations, modifications, and alternatives.

In a specific embodiment, the present invention uses a selected thickness for the quantum well to achieve different color emissions for a given or selected indium content. In a specific embodiment, the emission wavelength is controlled by a selected thickness of the quantum well region. In one or more embodiments, thicker quantum wells with the same indium content will often emit at longer wavelengths. In one or more other embodiments, the method and structures use a combination of differing indium and differing quantum well thicknesses to achieve different color emitting layers on the same device structure. As will be further demonstrated below, we have achieved different color emissions by changing indium composition according to one or more embodiments. Of course, there can be other variations, modifications, and alternatives.

In a preferred embodiment, the present method and structure achieves different emission colors by different thicknesses of emitting layers. That is, the method forms different thicknesses of emitting layers by way of either the use of different growth times for the two or more emitting layers given that both of the layers have similar or the same growth rates. Alternatively, the method forms different thicknesses of emitting layers by way of changing the growth rate of the different layers while maintaining the same growth time according to a specific embodiment. In yet other embodiments, the method and structure relies upon a combination of the two techniques, among others. Of course, there can be other variations, modifications, and alternatives.

In one or more embodiments that are free from a tunnel junction, different emitting quantum well layers are placed in the same p-i-n junction such that they share a common p-GaN cladding layer above or below the active region and a common n-GaN cladding layer on the other side. The different emitting layers are separated by barrier layers, which can be GaN, InGaN, AlGaN, or InAlGaN, combinations, and others. In one or more embodiments, including the experimental results noted below, the emitting layers were separated by GaN barriers. Of course, there can be other variations, modifications, and alternatives.

In still further embodiments, the present method and structures can include two or more emitting layers having substantially the same color emission or like emission. Depending upon the embodiment, the two or more emitting layers that have the same emission can be selectively introduced for color balancing and/or the like. Depending upon the embodiment, each of the substantially similar layers can be stacked sequentially or stacked in an arrangement with an intermediary emission layer or layers. Of course, there can be other variations, modifications, and alternatives.

Although the above has been described in terms of an embodiment of a specific package, there can be many variations, alternatives, and modifications. As an example, the LED device can be configured in a variety of packages such as cylindrical, surface mount, power, lamp, flip-chip, star, array, strip, or geometries that rely on lenses (silicone, glass) or sub-mounts (ceramic, silicon, metal, composite). Alternatively, the package can be any variations of these packages. Of course, there can be other variations, modifications, and alternatives.

In other embodiments, the packaged device can include one or more other types of optical and/or electronic devices. As an example, the optical devices can be OLED, a laser, a nanoparticle optical device, and others. In other embodiments, the electronic device can include an integrated circuit, a sensor, a micro-electro-mechanical system, or any combination of these, and the like. Of course, there can be other variations, modifications, and alternatives.

In a specific embodiment, the packaged device can be coupled to a rectifier to convert alternating current power to direct current, which is suitable for the packaged device. The rectifier can be coupled to a suitable base, such as an Edison screw such as E27 or E14, bipin base such as MR16 or GU5.3, or a bayonet mount such as GU10, or others. In other embodiments, the rectifier can be spatially separated from the packaged device. Of course, there can be other variations, modifications, and alternatives.

Additionally, the present packaged device can be provided in a variety of applications. In a preferred embodiment, the application is general lighting, which includes buildings for offices, housing, outdoor lighting, stadium lighting, and others. Alternatively, the applications can be for display, such as those used for computing applications, televisions, projectors, micro-, nano-, or pico-projectors, flat panels, micro-displays, and others. Still further, the applications can include automotive, gaming, and others. Of course, there can be other variations, modifications, and alternatives.

While the above is a full description of the specific embodiments, various modifications, alternative constructions and equivalents may be used. As an example, the sequence of the LED devices can be changed according to one or more embodiments. That is, the sequence of LED devices in a vertical configuration can be almost any sequence of yellow and blue or red green and blue, among others. Therefore, the above description and illustrations should not be taken as limiting the scope of the present invention which is defined by the appended claims.

### CITED PUBLICATIONS

[1] H. Zhong, A. Tyagi, N. N. Fellows, F. Wu, R. B. Chung, M. Saito, K. Fujito, J. S. Speck, S. P. DenBaars, and S. Nakamura, “High power and high efficiency blue light emitting diode on freestanding semipolar (1122) bulk GaN substrate,” Appl. Phys. Lett., vol. 90, 2007.
[2] H. Sato, A. Tyagi, H. Zhong, N. Fellows, R. Chung, M. Saito, K. Fujito, J. Speck, S. DenBaars, and S. Nakamura, “High power and high efficiency green light emitting diode on free-standing semipolar (1122) bulk GaN substrate,” Phys. Stat. Sol. (RRL), vol. 1, pp. 162-164, June 2007.
[3] H. Zhong, A. Tyagi, N. N. Fellows, R. B. Chung, M. Saito, K. Fujito, J. S. Speck, S. P. DenBaars, and S. Nakamura, “Demonstration of high power blue-green light emitting diode on semipolar (1122) bulk GaN substrate,” Elect. Lett., vol. 43, pp. 825-826.

What is claimed is:

1. A packaged light emitting device comprising:
a substrate member comprising a surface region;
two or more light emitting diode devices overlying the surface region, each of the light emitting diode device being fabricated on a semipolar or nonpolar GaN containing substrate, the two or more light emitting diode devices fabricated on the semipolar or nonpolar GaN containing substrate emits substantially polarized emission.

2. The device of claim 1 wherein the two or more light emitting diode device comprising a blue LED device and a yellow LED device, the substantially polarized emission being white light.

3. The device of claim 1 wherein the two or more light emitting diode device comprises an array of LED devices comprising a pair of blue LED devices and a pair of yellow LED devices.

4. The device of claim 1 wherein the two or more light emitting diode devices comprises at least a red LED device, a blue LED device, and a green LED device.

5. A monolithic light emitting device comprising:
a bulk GaN containing semipolar or nonpolar substrate comprising a surface region;
an n-type GaN containing layer overlying the surface region, the n-type GaN containing layer having a first region and a second region;
a first LED device region provided on the first region, the first LED device region having a first color characteristic; and
a second LED device region provided on the second region, the second LED device region having a second color characteristic.

6. The device of claim 5 wherein the first color characteristic is yellow and the second color characteristic is blue.

7. The device of claim 6 further comprising a third LED device region provided on a third region, the third LED device region having a third color characteristic, the third color characteristic being red or green.

8. A monolithic light emitting device comprising:
a bulk GaN containing semipolar or nonpolar substrate comprising a surface region;
an n-type GaN containing layer overlying the surface region, the n-type GaN containing layer having a first region and a second region;
a first LED device region provided on the first region, the first LED device region having a first color characteristic;
a second LED device region provided on the second region, the second LED device region having a second color characteristic; and
a third LED device region provided on the third region, the third LED device region having a third color characteristic.

9. The device of claim 8 wherein the first characteristic is blue, the second characteristic is green, and the third characteristic is red.

10. A light emitting device comprising:
a bulk GaN containing semipolar or nonpolar substrate, the bulk GaN containing semipolar or nonpolar substrate comprising a surface region and a bottom region;
an n-type GaN containing material overlying the surface region;
a blue LED device region overlying the surface region;
a yellow LED device region overlying the blue LED device region to form a stacked structure.

11. The device of claim 10 further comprising a red LED device region overlying the blue LED device region.

12. The device of claim 10 wherein the blue LED device region and the yellow LED device region are configured to emit substantially polarized emission.

13. A light emitting device comprising:
a bulk GaN containing semipolar or nonpolar substrate, the bulk GaN containing semipolar or nonpolar substrate comprising a surface region and a bottom region;
an n-type GaN containing material overlying the surface region;
a blue LED device region overlying the surface region;
a green LED device region overlying the blue LED device region;
a red LED device region overlying the green LED device region to form a stacked structure.

14. A light emitting device comprising:
a bulk GaN semipolar or nonpolar substrate comprising a surface region;
an n-type GaN containing layer overlying the surface region;
an InGaN active region overlying the surface region;
a blue emitting region within a first portion of the InGaN active region;
a yellow emitting region within a second portion of the InGaN active region;
a p-type GaN containing layer overlying the InGaN active region.

15. A light emitting device comprising:
a bulk GaN semipolar or nonpolar substrate comprising a surface region;
an n-type GaN containing layer overlying the surface region;
an InGaN active region overlying the surface region;
a blue emitting region within a first portion of the InGaN active region;
a green emitting region within a second portion of the InGaN active region;
a red emitting region within a third portion of the InGaN active region; and
a p-type GaN containing layer overlying the InGaN active region.

16. A light emitting device comprising:
a bulk GaN containing semipolar or nonpolar substrate, the bulk GaN containing semipolar or nonpolar substrate comprising a surface region and a bottom region;
an n-type GaN containing material overlying the surface region;
a blue LED device region coupled to the surface region;
a green LED device region coupled to the surface region;
a red LED device region coupled to the surface region to form a stacked structure.

17. A light emitting device comprising:
a bulk GaN containing semipolar or nonpolar substrate, the bulk GaN containing semipolar or nonpolar substrate comprising a surface region and a bottom region;
an n-type GaN containing material overlying the surface region;
a blue LED device region coupled to the surface region;
a yellow LED device region coupled to the blue LED device region to form a stacked structure.

18. The device of claim 17 wherein the blue LED device region is overlying the yellow LED device region.

19. The device of claim 17 wherein the yellow LED device region is overlying the blue LED device region.

20. A method for packaged light emitting device comprising:
providing a substrate member comprising a surface region, the substrate member comprising a semipolar or nonpolar GaN containing substrate; and
forming two or more light emitting diode devices overlying the surface region, the two or more light emitting diode devices fabricated on the semipolar or nonpolar GaN containing substrate providing substantially polarized emission.

21. The method of claim 20 wherein the two or more light emitting diode devices comprising a blue LED region and a yellow LED region.

22. The method of claim 20 wherein the two or more light emitting diode device comprising a blue LED device and a yellow LED device, the substantially polarized emission being white light.

23. The method of claim 20 wherein the two or more light emitting diode device comprises an array of LED devices comprising a pair of blue LED devices and a pair of yellow LED devices.

24. The method of claim 20 wherein the two or more light emitting diode devices comprises at least a red LED device, a blue LED device, and a green LED device.

25. A method of fabricating a monolithic light emitting device, the method comprising:
providing a bulk GaN containing semipolar or nonpolar substrate comprising a surface region;
forming an n-type GaN containing layer overlying the surface region, the n-type GaN containing layer having a first region and a second region;
forming a first LED device region provided on the first region, the first LED device region having a first color characteristic; and
forming a second LED device region provided on the second region, the second LED device region having a second color characteristic.

26. The method of claim 25 wherein the first color characteristic is yellow and the second color characteristic is blue.

27. The method of claim 26 further comprising forming a third LED device region provided on a third region, the third LED device region having a third color characteristic, the third color characteristic being red or green.

28. A method of forming monolithic light emitting device, the method comprising:
providing a bulk GaN containing semipolar or nonpolar substrate comprising a surface region;
forming an n-type GaN containing layer overlying the surface region, the n-type GaN containing layer having a first region and a second region;
forming a first LED device region provided on the first region, the first LED device region having a first color characteristic;
forming a second LED device region provided on the second region, the second LED device region having a second color characteristic; and
forming a third LED device region provided on the third region, the third LED device region having a third color characteristic.

29. The method of claim 28 wherein the first characteristic is blue, the second characteristic is green, and the third characteristic is red.

30. A method of fabricating a light emitting device, the method comprising:
providing a bulk GaN containing semipolar or nonpolar substrate, the bulk GaN containing semipolar or nonpolar substrate comprising a surface region and a bottom region;
forming an n-type GaN containing material overlying the surface region;
forming a blue LED device region overlying the surface region; and
forming a yellow LED device region overlying the blue LED device region to form a stacked structure.

31. The method of claim 30 further comprising forming a red LED device region overlying the blue LED device region.

32. The method of claim 30 wherein the blue LED device region and the yellow LED device region are configured to emit substantially polarized emission.

33. A method of fabricating a light emitting device, the method comprising:
providing a bulk GaN containing semipolar or nonpolar substrate, the bulk GaN containing semipolar or nonpolar substrate comprising a surface region and a bottom region;
forming an n-type GaN containing material overlying the surface region;
forming a blue LED device region overlying the surface region;
forming a green LED device region overlying the blue LED device region; and
forming a red LED device region overlying the green LED device region to form a stacked structure.

34. A method for fabricating a light emitting device, the method comprising:
providing a bulk GaN semipolar or nonpolar substrate comprising a surface region;
forming an n-type GaN containing layer overlying the surface region;
forming an InGaN active region overlying the surface region;
forming a blue emitting region within a first portion of the InGaN active region;
forming a yellow emitting region within a second portion of the InGaN active region; and
forming a p-type GaN containing layer overlying the InGaN active region.

35. A light emitting device comprising:
providing a bulk GaN semipolar or nonpolar substrate comprising a surface region;
forming an n-type GaN containing layer overlying the surface region;
forming an InGaN active region overlying the surface region;
forming a blue emitting region within a first portion of the InGaN active region;
forming a green emitting region within a second portion of the InGaN active region;
forming a red emitting region within a third portion of the InGaN active region; and
forming a p-type GaN containing layer overlying the InGaN active region.

36. A method for fabricating a light emitting device, the method comprising:
providing a bulk GaN containing semipolar or nonpolar substrate, the bulk GaN containing semipolar or nonpolar substrate comprising a surface region and a bottom region;
forming an n-type GaN containing material overlying the surface region;
forming a blue LED device region coupled to the surface region;
forming a green LED device region coupled to the surface region;
forming a red LED device region coupled to the surface region to form a stacked structure.

37. A method for fabricating a light emitting device, the method comprising:
providing a bulk GaN containing semipolar or nonpolar substrate, the bulk GaN containing semipolar or nonpolar substrate comprising a surface region and a bottom region;
forming an n-type GaN containing material overlying the surface region;
forming a blue LED device region coupled to the surface region; and
forming a yellow LED device region coupled to the blue LED device region to form a stacked structure.

38. The method of claim 37 wherein the blue LED device region is overlying the yellow LED device region.

39. The method of claim 37 wherein the yellow LED device region is overlying the blue LED device region.
